(19) United States
(12) Patent Application Publication
(10) Pub. No.: US 2025/0047248 A1
(43) Pub. Date: Feb. 6, 2025

(54) POWER AMPLIFIER CIRCUIT

(71) Applicant: Murata Manufacturing Co., Ltd., Kyoto (JP)

(72) Inventor: Yoshiaki SUKEMORI, Kyoto (JP)

(21) Appl. No.: 18/771,192

(22) Filed: Jul. 12, 2024

(30) Foreign Application Priority Data
Jul. 31, 2023 (JP) 2023-125013
Nov. 29, 2023 (JP) 2023-201465

(51) Int. Cl. H03F 3/213

(52) U.S. Cl. CPC H03F 3/213; H03F 2200/451

(57) ABSTRACT

A power amplifier circuit includes a first transistor; a second transistor; and a third transistor on the semiconductor substrate; a first metal part that is electrically connected to an emitter of the first transistor and is disposed, in plan view of the semiconductor substrate, to overlap a first layout region in which the first transistor is disposed; and a second metal part that is electrically connected to the emitter of the third transistor. The third transistor is disposed to overlap the first metal part in the plan view.

### CROSS REFERENCE TO RELATED APPLICATION

This application claims priority from Japanese Patent Application No. 2023-125013 filed on Jul. 31, 2023 and Japanese Patent Application No. 2023-201465 filed on Nov. 29, 2023. The contents of these applications are incorporated herein by reference in their entireties.

### BACKGROUND ART

The present disclosure relates to a power amplifier circuit.

Japanese Unexamined Patent Application Publication No. 2021-125870 discloses a power amplifier circuit that can reduce the influence of stress.

### BRIEF SUMMARY

An amplifier transistor heats up when, for example, the amplifier transistor is biased or amplifies a radio frequency signal. When such an amplifier transistor heats up, the threshold of the base-emitter voltage changes, the operating point changes, the gain changes, and the linearity is influenced. As a result, the output characteristics of a power amplifier circuit are degraded.

In the power amplifier circuit disclosed in Japanese Unexamined Patent Application Publication No. 2021-125870, although stress received by an amplifier transistor and a bias transistor is considered, heat generation of the amplifier transistor is not considered.

The present disclosure reduces the degradation of output characteristics of a power amplifier circuit.

According to an aspect of this disclosure, a power amplifier circuit includes a first transistor formed on a semiconductor substrate; a second transistor that is formed on the semiconductor substrate, includes a base to which a first current is supplied as a part of control currents, and supplies a bias current based on the first current to the first transistor; a third transistor that is formed on the semiconductor substrate, includes a collector to which a second current is supplied as a part of the control currents, and includes an emitter that outputs a third current based on the second current; a first metal part that is electrically connected to an emitter of the first transistor and is disposed, in plan view of the semiconductor substrate, to overlap a first layout region in which the first transistor is disposed; and a second metal part that is electrically connected to the emitter of the third transistor. The third transistor is disposed to overlap the first metal part in the plan view.

The present disclosure makes it possible to reduce the degradation of output characteristics of a power amplifier circuit.

### BRIEF DESCRIPTION OF THE DRAWINGS

FIG. 1 is a diagram illustrating a circuit configuration of a power amplifier circuit according to a first embodiment;

FIG. 2 is a diagram illustrating a layout of the power amplifier circuit according to the first embodiment;

FIG. 3 is a cross-sectional view of the power amplifier circuit according to the first embodiment;

FIG. 4 is a diagram illustrating a circuit configuration of a power amplifier circuit according to a second embodiment;

FIG. 5 is a diagram illustrating a layout of the power amplifier circuit according to the second embodiment;

FIG. 6 is a diagram illustrating a circuit configuration of a power amplifier circuit according to a third embodiment;

FIG. 7 is a diagram illustrating a layout of the power amplifier circuit according to the third embodiment;

FIG. 8 is a diagram illustrating a circuit configuration of a power amplifier circuit according to a fourth embodiment;

FIG. 9 is a diagram illustrating a layout of the power amplifier circuit according to the fourth embodiment;

FIG. 10 is a cross-sectional view of the power amplifier circuit according to the fourth embodiment; and

FIG. 11 is a diagram illustrating a layout of a power amplifier circuit according to a fifth embodiment.

### DETAILED DESCRIPTION

Embodiments of the present disclosure are described in detail below with reference to the drawings. However, the present disclosure is not limited to the embodiments described below. Needless to say, the embodiments are examples, and partial substitutions and combinations of components in different embodiments may be made. In the second and subsequent embodiments, descriptions of features that are the same as those in the first embodiment are omitted, and only differences are described. In particular, the description of the same effect provided by the same feature is not repeated for each embodiment.

### First Embodiment

### Circuit Configuration

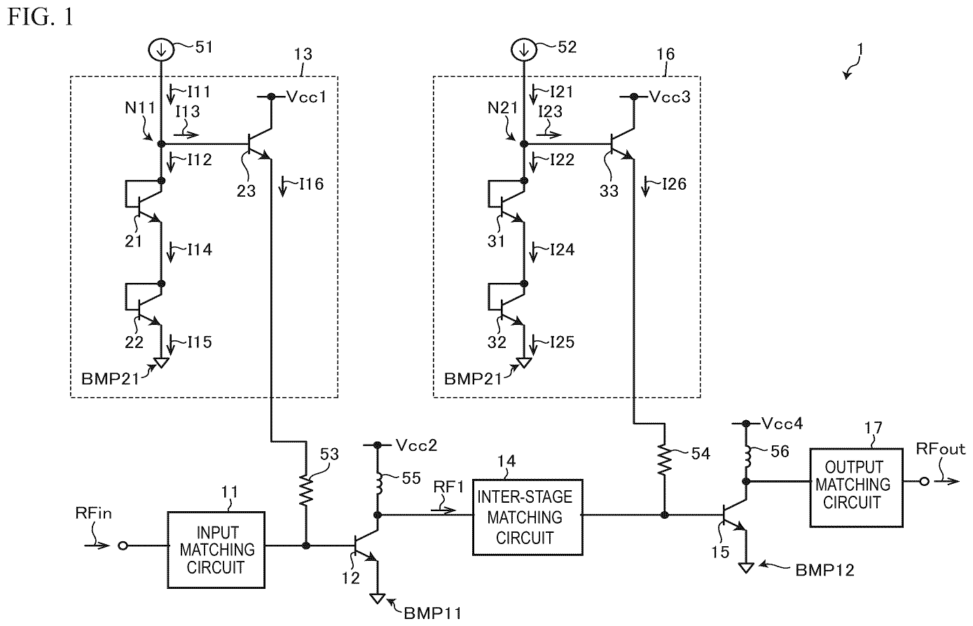

FIG. 1 is a diagram illustrating a circuit configuration of a power amplifier circuit according to a first embodiment. A power amplifier circuit 1 amplifies a radio frequency signal RFin and outputs a radio frequency signal RFout.

The power amplifier circuit 1 includes an input matching circuit 11, a first-stage (driver-stage) amplifier transistor 12, a bias circuit 13, an inter-stage matching circuit 14, a final-stage (power-stage) amplifier transistor 15, a bias circuit 16, and an output matching circuit 17.

Each of the amplifier transistor 12 and the amplifier transistor 15 is an example of a “first transistor” of the present disclosure.

For example, each transistor is a bipolar transistor. However, the present disclosure is not limited to this example. Each transistor may instead be, for example, a field-effect transistor. An example of a bipolar transistor is a heterojunction bipolar transistor (HBT), but the present disclosure is not limited to this example. Each transistor may also be a multi-finger transistor implemented by electrically connecting multiple unit transistors in parallel with each other. A unit transistor refers to a transistor with the minimum configuration.

When each transistor is a field-effect transistor, the source corresponds to the emitter of the bipolar transistor, the gate corresponds to the base of the bipolar transistor, and the drain corresponds to the collector of the bipolar transistor.

In the present embodiment, it is assumed that each of the amplifier transistor 12 and the amplifier transistor 15 is a multi-finger transistor. However, the present disclosure is not limited to this embodiment. Each of the amplifier transistor 12 and the amplifier transistor 15 may be a unit transistor.

In the present embodiment, it is assumed that the number of stages of the power amplifier circuit 1 is two. However, the present disclosure is not limited to this embodiment. The number of stages of the power amplifier circuit 1 may be one or may be three or more.

A radio frequency signal RFin is input to a first end of the input matching circuit 11. A second end of the input matching circuit 11 is electrically connected to the base of the amplifier transistor 12. The radio frequency signal RFin passed through the input matching circuit 11 is input to the base of the amplifier transistor 12.

The bias circuit 13 biases the amplifier transistor 12. The bias circuit 13 includes transistors 21 through 23. The transistor 23 is an example of a “second transistor” of the present disclosure. The transistor 22 is an example of a “third transistor” of the present disclosure. The transistor 21 is an example of a “fifth transistor” of the present disclosure.

In the present embodiment, each of the transistors 21 through 23 is assumed to be a unit transistor. However, the present disclosure is not limited to this embodiment. Each of the transistors 21 through 23 may be a multi-finger transistor.

The collector and the base of the transistor 21 are electrically connected to a node N11. That is, the transistor 21 is diode-connected. The emitter of the transistor 21 is electrically connected to the collector and the base of the transistor 22. That is, the transistor 22 is diode-connected. Each of the transistor 21 and the transistor 22 may be replaced with a transistor that includes a feedback circuit between the base and the collector. The emitter of the transistor 22 is electrically connected to a bump BMP21 (described later). The bump BMP21 is electrically connected to a reference potential. That is, the emitter of the transistor 22 is electrically connected to the reference potential via the bump BMP21. The reference potential is, for example, a ground potential. However, the present disclosure is not limited to this example.

The base of the transistor 23 is electrically connected to the node N11. The collector of the transistor 23 is electrically connected to and receives power from a power supply potential Vcc1. The emitter of the transistor 23 is electrically connected to a first end of a resistor 53. In other words, the transistor 23 is connected to the resistor 53 in an emitter-follower configuration. A second end of the resistor 53 is electrically connected to the base of the amplifier transistor 12.

An electric current I11 is input from a current source 51 to the node N11. The electric current I11 is divided into an electric current I12 and an electric current I13. That is, I11=I12+I13.

The electric current I11 is an example of a “control current” of the present disclosure. The electric current I12 is an example of a “fifth current” of the present disclosure. The electric current I13 is an example of a “first current” of the present disclosure.

The electric current I12 is input to the collector and the base of the transistor 21. The transistor 21 outputs an electric current I14 from the emitter to the collector and the base of the transistor 22. That is, I12=I14. The transistor 22 outputs an electric current I15 from the emitter to the bump BMP21. That is, I14=I15. The transistor 21 and the transistor 22 generate a voltage at the node N11.

The electric current I14 is an example of a “second current” of the present disclosure. The electric current I15 is an example of a “third current” of the present disclosure.

The transistor 23 outputs an electric current I16 corresponding to the electric current I13 to the base of the amplifier transistor 12 via the resistor 53. The base of the amplifier transistor 12 is biased by the electric current I16. That is, the electric current I16 is a base bias current of the amplifier transistor 12.

The emitter of the amplifier transistor 12 is electrically connected to a bump BMP11 (described later). The bump BMP11 is electrically connected to the reference potential. That is, the emitter of the amplifier transistor 12 is electrically connected to the reference potential via the bump BMP11. The collector of the amplifier transistor 12 is electrically connected to and receives power from a power supply potential Vcc2 via a choke coil 55. The collector of the amplifier transistor 12 is also electrically connected to a first end of the inter-stage matching circuit 14. The amplifier transistor 12 amplifies the radio frequency signal RFin input to the base and outputs an amplified radio frequency signal RF1 from the collector to a first end of the inter-stage matching circuit 14.

A second end of the inter-stage matching circuit 14 is electrically connected to the base of the amplifier transistor 15. The radio frequency signal RF1 passed through the inter-stage matching circuit 14 is input to the base of the amplifier transistor 15.

The bias circuit 16 biases the amplifier transistor 15. The bias circuit 16 includes transistors 31 through 33.

The transistor 33 is an example of a “second transistor” of the present disclosure. The transistor 32 is an example of a “third transistor” of the present disclosure. The transistor 31 is an example of a “fifth transistor” of the present disclosure.

In the present embodiment, each of the transistors 31 through 33 is assumed to be a unit transistor. However, the present disclosure is not limited to this embodiment. Each of the transistors 31 through 33 may be a multi-finger transistor.

The collector and the base of the transistor 31 are electrically connected to a node N21. That is, the transistor 31 is diode-connected. The emitter of the transistor 31 is electrically connected to the collector and the base of the transistor 32. That is, the transistor 32 is diode-connected. Each of the transistor 31 and the transistor 32 may be replaced with a transistor that includes a feedback circuit between the base and the collector. The emitter of the transistor 32 is electrically connected to a bump BMP21 (described later). The bump BMP21 is electrically connected to the reference potential. That is, the emitter of the transistor 32 is electrically connected to the reference potential via the bump BMP21.

The base of the transistor 33 is electrically connected to the node N21. The collector of the transistor 33 is electrically connected to and receives power from a power supply potential Vcc3. The emitter of the transistor 33 is electrically connected to a first end of a resistor 54. In other words, the transistor 33 is connected to the resistor 54 in an emitter-follower configuration. A second end of the resistor 54 is electrically connected to the base of the amplifier transistor 15.

An electric current I21 is input from a current source 52 to the node N21. The electric current I21 is divided into an electric current I22 and an electric current I23. That is, I21=I22+I23.

The electric current I21 is an example of a “control current” of the present disclosure. The electric current I23 is an example of a “first current” of the present disclosure.

The electric current I22 is input to the collector and the base of the transistor 31. The transistor 31 outputs an electric current I24 from the emitter to the collector and the base of the transistor 32. That is, I22=I24. The transistor 32 outputs an electric current I25 from the emitter to the bump BMP21. That is, I24=I25. The transistor 31 and the transistor 32 generate a voltage at the node N21.

The electric current I24 is an example of a “second current” of the present disclosure. The electric current I25 is an example of a “third current” of the present disclosure.

The transistor 33 outputs an electric current I26 corresponding to the electric current I23 to the base of the amplifier transistor 15 via the resistor 54. The base of the amplifier transistor 15 is biased by the electric current I26. That is, the electric current I26 is a base bias current of the amplifier transistor 15.

The emitter of the amplifier transistor 15 is electrically connected to a bump BMP12 (described later). The bump BMP12 is electrically connected to the reference potential. That is, the emitter of the amplifier transistor 15 is electrically connected to the reference potential via the bump BMP12. The collector of the amplifier transistor 15 is electrically connected to and receives power from a power supply potential Vcc4 via a choke coil 56. The collector of the amplifier transistor 15 is also electrically connected to a first end of the output matching circuit 17. The amplifier transistor 15 amplifies the radio frequency signal RF1 input to the base and outputs an amplified radio frequency signal RFout from the collector to the first end of the output matching circuit 17. A radio frequency signal RFout is output from a second end of the output matching circuit 17.

### Layout

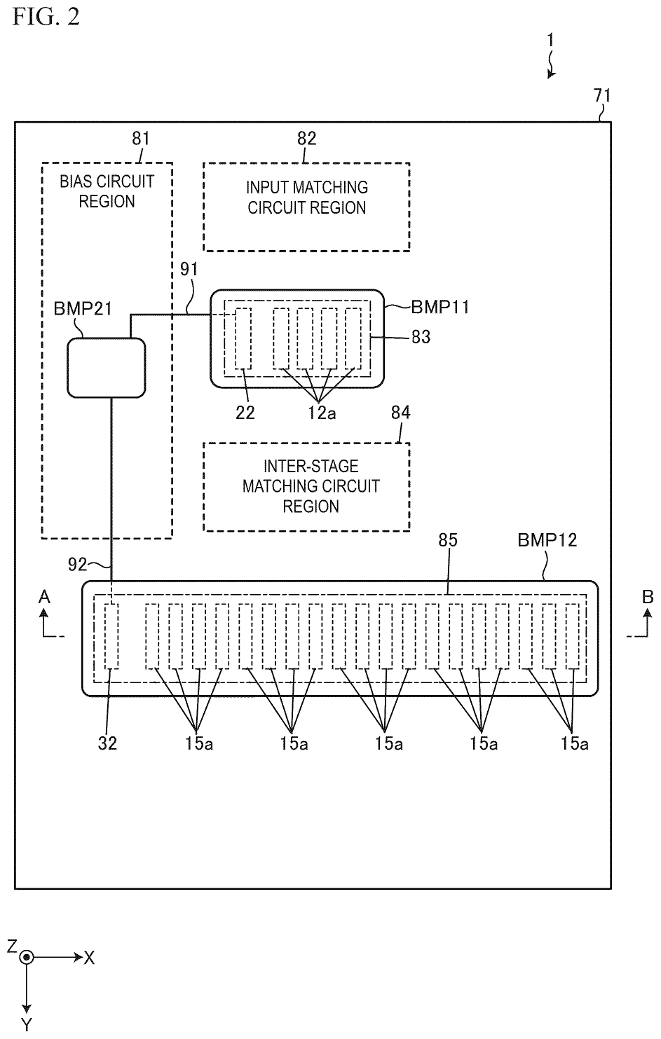

FIG. 2 illustrates a layout of the power amplifier circuit of the first embodiment. The power amplifier circuit 1 is formed on or in a semiconductor substrate 71. FIG. 2 is a plan view of the semiconductor substrate 71 seen from a direction perpendicular to the major surface. In FIG. 2, a region where the output matching circuit 17 is formed is omitted.

A bias circuit region 81 is provided along the left side (or a side closer to the base of the X-axis and extending along the Y-axis) of the semiconductor substrate 71 in the figure. The longitudinal direction of the bias circuit region 81 corresponds to the Y-axis direction, and the transverse direction of the bias circuit region 81 corresponds to the X-axis direction. The transistor 21 and the transistor 23 of the bias circuit 13 and the transistor 31 and the transistor 33 of the bias circuit 16 are formed in the bias circuit region 81.

The bump BMP21 is formed, via an insulating layer (described later), in an upper layer (or a foreground layer in the figure) substantially in the middle of the bias circuit region 81.

The bump BMP21 is an example of a “second metal part” of the present disclosure.

For example, copper (Cu) is used for the bump BMP21. A low-resistance metallic material other than copper, such as aluminum (Al) or gold (Au), may also be used for the bump BMP21.

An under bump metal (UBM) may be formed between the insulating layer and the bump BMP21. The under bump metal is formed of, for example, a material containing at least one of Ti, Cr, Cu, Au, Ni, and Pd.

An input matching circuit region 82 is provided on the right side (or a side facing the X-axis direction) of an upper part (or a part closer to the base of the Y-axis) of the bias circuit region 81 in the figure. The longitudinal direction of the input matching circuit region 82 corresponds to the X-axis direction, and the transverse direction of the input matching circuit region 82 corresponds to the Y-axis direction. The input matching circuit 11 is formed in the input matching circuit region 82.

A region 83 is provided, in the figure, on the right side (or a side facing the X-axis direction) of a central part (a central part in the Y-axis direction) of the bias circuit region 81 and on the lower side (or a side facing the Y-axis direction) of the input matching circuit region 82. The longitudinal direction of the region 83 corresponds to the X-axis direction, and the transverse direction of the region 83 corresponds to the Y-axis direction. The transistor 22 and multiple unit transistors 12a are formed in the region 83. The multiple unit transistors 12a constitute the amplifier transistor 12.

The region 83 is an example of a “first layout region” of the present disclosure.

The transistor 22 is formed along the left side (or a side closer to the base of the X-axis) of the region 83 in the figure. Also, the multiple unit transistors 12a are formed on the right side (or a side facing the X-axis direction) of the transistor 22. The longitudinal direction of each of the transistor 22 and the multiple unit transistors 12a corresponds to the Y-axis direction, and the transverse direction of each of the transistor 22 and the multiple unit transistors 12a corresponds to the X-axis direction. The transistor 22 and the multiple unit transistors 12a are arranged in the longitudinal direction of the region 83 (or in the X-axis direction).

The emitter of the transistor 22 is electrically connected to the bump BMP21 via a wire 91 formed on or in the semiconductor substrate 71.

The bump BMP11 is formed in an upper layer (or a foreground layer in the figure) of the region 83 via an insulating layer (described later). The bump BMP11 overlaps the region 83 (the transistor 22 and the multiple unit transistors 12a) in plan view. Here, “plan view” refers to a view of the semiconductor substrate 71 from a direction perpendicular to the major surface of the semiconductor substrate 71 (or a direction opposite to the Z-axis direction).

The bump BMP11 is an example of a “first metal part” of the present disclosure.

For example, copper (Cu) is used for the bump BMP11. A low-resistance metallic material other than copper, such as aluminum (Al) or gold (Au), may also be used for the bump BMP11.

An under bump metal (UBM) may be formed between the insulating layer and the bump BMP11.

The emitter of each of the multiple unit transistors 12a is electrically connected to the bump BMP11 through a via (described below).

An inter-stage matching circuit region 84 is provided, in the figure, on the right side (or a side facing the X-axis direction) of a lower part (or a part facing the Y-axis direction) of the bias circuit region 81 and on the lower side (or a side facing the Y-axis direction) of the region 83. The longitudinal direction of the inter-stage matching circuit region 84 corresponds to the X-axis direction, and the transverse direction of the inter-stage matching circuit region 84 corresponds to the Y-axis direction. The inter-stage matching circuit 14 is formed in the inter-stage matching circuit region 84.

A region 85 is provided, in the figure, on the lower sides (or sides facing the Y-axis direction) of the bias circuit region 81 and the inter-stage matching circuit region 84. The longitudinal direction of the region 85 corresponds to the X-axis direction, and the transverse direction of the region 85 corresponds to the Y-axis direction. The transistor 32 and multiple unit transistors 15a are formed in the region 85. The multiple unit transistors 15a constitute the amplifier transistor 15.

The region 85 is an example of a “first layout region” of the present disclosure.

The transistor 32 is formed along the left side (or a side closer to the base of the X-axis) of the region 85 in the figure. Also, the multiple unit transistors 15a are formed on the right side (or a side facing the X-axis direction) of the transistor 32 in the figure. The longitudinal direction of each of the transistor 32 and the multiple unit transistors 15a corresponds to the Y-axis direction, and the transverse direction of each of the transistor 32 and the multiple unit transistors 15a corresponds to the X-axis direction. The transistor 32 and the multiple unit transistors 15a are arranged in the longitudinal direction of the region 85 (or in the X-axis direction).

The emitter of the transistor 32 is electrically connected to the bump BMP21 via a wire 92 formed on or in the semiconductor substrate 71.

The bump BMP12 is formed in an upper layer (or a foreground layer in the figure) of the region 85 via an insulating layer (described later). The bump BMP12 overlaps the region 85 (the transistor 32 and the multiple unit transistors 15a) in plan view. Here, “plan view” refers to a view of the semiconductor substrate 71 from a direction perpendicular to the major surface of the semiconductor substrate 71 (or a direction opposite to the Z-axis direction).

The bump BMP12 is an example of a “first metal part” of the present disclosure.

For example, copper (Cu) is used for the bump BMP12. A low-resistance metallic material other than copper, such as aluminum (Al) or gold (Au), may also be used for the bump BMP12.

An under bump metal may be formed between the insulating layer and the bump BMP12.

The emitter of each of the multiple unit transistors 15a is electrically connected to the bump BMP12 through a via (described below).

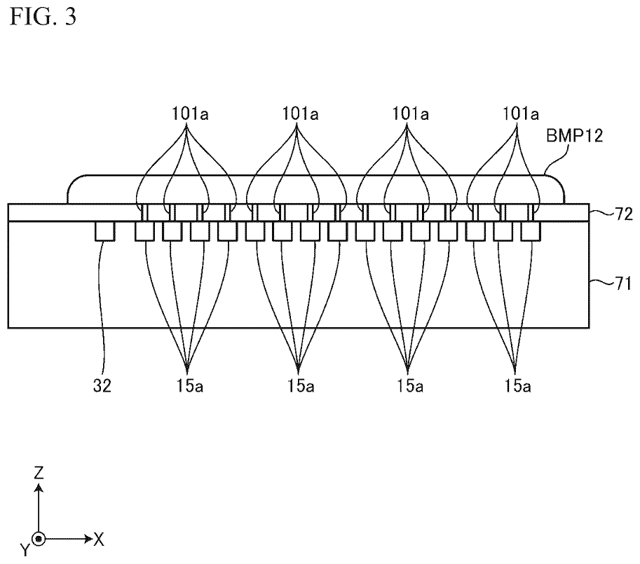

FIG. 3 is a cross-sectional view of the power amplifier circuit according to the first embodiment. FIG. 3 is a cross-sectional view taken along line A-B in FIG. 2.

FIG. 3 illustrates cross sections of the transistor 32, the multiple unit transistors 15a, and the bump BMP12. Because the cross sections of the transistor 22, the multiple unit transistors 12a, and the bump BMP11 are substantially the same as those in FIG. 3, their illustration and descriptions are omitted.

The transistor 32 and the multiple unit transistors 15a are formed on or in the semiconductor substrate 71. An insulating layer 72 is formed in a layer above the transistor 32 and the multiple unit transistors 15a (or a layer in the Z-axis direction). The bump BMP12 is formed in a layer above the insulating layer 72 (or a layer in the Z-axis direction). The emitters of the multiple unit transistors 15a are electrically connected to the bump BMP12 through multiple vias 101a.

An under bump metal may be formed between the insulating layer 72 and the bump BMP12. In this case, the multiple vias 101a are electrically connected to the under bump metal.

Here, the emitter of the transistor 32 is electrically connected to the bump BMP21 (see FIG. 2) via the wire 92 (see FIG. 2) and is therefore not electrically connected to the bump BMP12.

### Effects

The amplifier transistor 15 (the multiple unit transistors 15a) heats up when, for example, the amplifier transistor 15 is biased or amplifies a radio frequency signal. When the amplifier transistor 15 heats up, the threshold of the base-emitter voltage decreases, the operating point changes, the quiescent current changes, the gain changes, and as a result, the linearity is degraded.

Referring to FIG. 3, heat generated by the multiple unit transistors 15a is transferred to the transistor 32 via the semiconductor substrate 71 and the insulating layer 72. In other words, the multiple unit transistors 15a and the transistor 32 are thermally coupled to each other. When the heat is transferred to the transistor 32 and the temperature of the transistor 32 increases, the threshold of the base-emitter voltage decreases.

Referring to FIG. 1, when the threshold of the base-emitter voltage of the transistor 32 decreases, the electric current I25 increases, the electric current I24 increases, and the electric current I22 increases. As a result, the electric current I23 decreases. The transistor 33 decreases the electric current I26 when the electric current I23 decreases. That is, the base bias current (the electric current I26) applied to the amplifier transistor 15 decreases. Accordingly, the change in the threshold of the base-emitter voltage of the amplifier transistor 15 due to the temperature increase is compensated for by the decrease in the base bias current (the electric current I26).

This makes it possible to reduce the degradation of the output characteristics of the power amplifier circuit 1 even when the amplifier transistor 15 heats up.

The amplifier transistor 12 and the bias circuit 13 also operate similarly to the amplifier transistor 15 and the bias circuit 16 described above. This makes it possible to reduce the degradation of the output characteristics of the power amplifier circuit 1 even when the amplifier transistor 12 heats up.

In the first embodiment, it is assumed that the technology of the present disclosure is applied to both stages of a multi-stage amplifier circuit (that is, the amplifier transistor 12 and the bias circuit 13, and the amplifier transistor 15 and the bias circuit 16). However, the present disclosure is not limited to this embodiment. The technology of the present disclosure may be applied to at least one of the stages of a multi-stage amplifier circuit.

### Second Embodiment

### Circuit Configuration

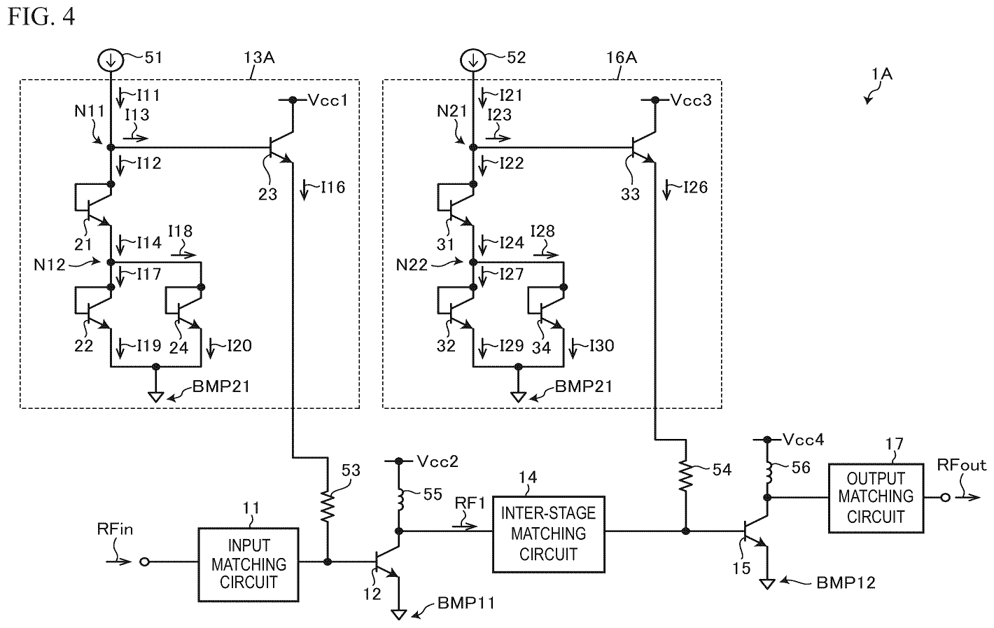

FIG. 4 is a diagram illustrating a circuit configuration of a power amplifier circuit according to a second embodiment.

Different from the power amplifier circuit 1 (see FIG. 1), a power amplifier circuit 1A includes a bias circuit 13A instead of the bias circuit 13. Also, the power amplifier circuit 1A includes a bias circuit 16A instead of the bias circuit 16.

Compared to the bias circuit 13, the bias circuit 13A further includes a transistor 24.

The transistor 24 is an example of a “fourth transistor” of the present disclosure.

In the present embodiment, the transistors 24 is assumed to be a unit transistor. However, the present disclosure is not limited to this embodiment. The transistor 24 may be a multi-finger transistor.

The collector and the base of the transistor 24 are electrically connected to a node N12 between the emitter of the transistor 21 and the collector of the transistor 22. That is, the transistor 24 is diode-connected. The emitter of the transistor 24 is electrically connected to the bump BMP21.

That is, the transistor 22 and the transistor 24 are connected in parallel with each other.

The size of the transistor 22 may be different from or the same as the size of the transistor 24.

The transistor 21 outputs the electric current I14 to the node N12. The electric current I14 is divided into an electric current I17 and an electric current I18. That is, I14=I17+I18.

The electric current I14 is an example of a “second current” of the present disclosure.

The electric current I17 is input to the collector and the base of the transistor 22. The transistor 22 outputs an electric current I19 from the emitter to the bump BMP21. That is, I17=I19.

The electric current I18 is input to the collector and the base of the transistor 24. The transistor 24 outputs an electric current I20 from the emitter to the bump BMP21. That is, I18=I20.

The electric current I20 is an example of a “fourth current” of the present disclosure.

Compared to the bias circuit 16, the bias circuit 16A further includes a transistor 34.

The transistor 34 is an example of a “fourth transistor” of the present disclosure.

In the present embodiment, the transistor 34 is assumed to be a unit transistor. However, the present disclosure is not limited to this embodiment. The transistor 34 may be a multi-finger transistor.

The collector and the base of the transistor 34 are electrically connected to a node N22 between the emitter of the transistor 31 and the collector of the transistor 32. That is, the transistor 34 is diode-connected. The emitter of the transistor 34 is electrically connected to the bump BMP21.

That is, the transistor 32 and the transistor 34 are connected in parallel with each other.

The size of the transistor 32 may be different from or the same as the size of the transistor 34.

The transistor 31 outputs the electric current I24 to the node N22. The electric current I24 is divided into an electric current I27 and an electric current I28. That is, I24=I27+I28.

The electric current I24 is an example of a “second current” of the present disclosure.

The electric current I27 is input to the collector and the base of the transistor 32. The transistor 32 outputs an electric current I29 from the emitter to the bump BMP21. That is, I27=I29.

The electric current I28 is input to the collector and the base of the transistor 34. The transistor 34 outputs an electric current I30 from the emitter to the bump BMP21. That is, I28=I30.

The electric current I30 is an example of a “fourth current” of the present disclosure.

### Layout

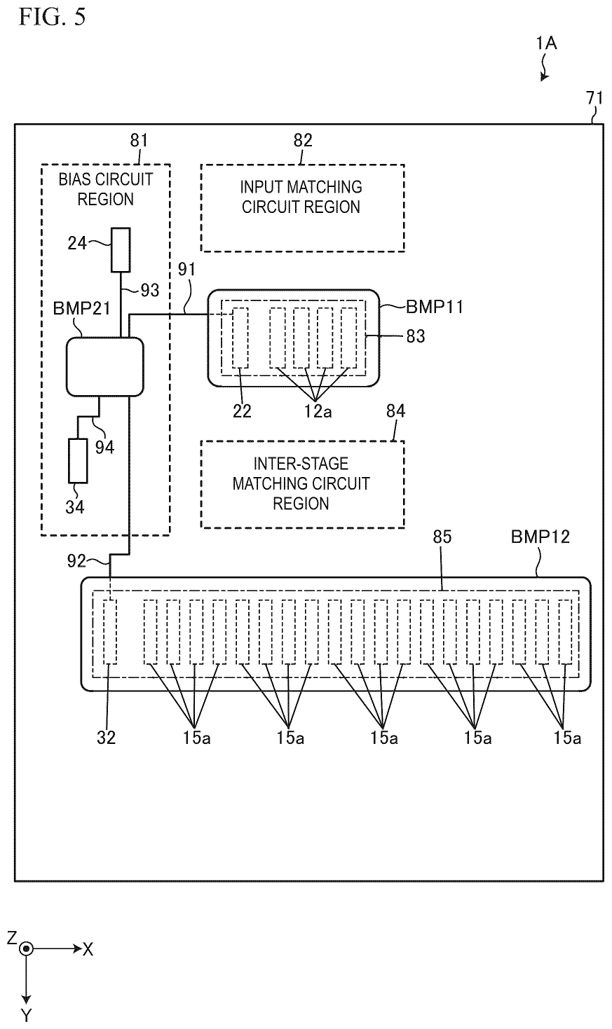

FIG. 5 is a diagram illustrating a layout of the power amplifier circuit according to the second embodiment. The power amplifier circuit 1A is formed on or in the semiconductor substrate 71. FIG. 5 is a plan view of the semiconductor substrate 71 seen from a direction perpendicular to the major surface.

In the power amplifier circuit 1A, different from the power amplifier circuit 1 (see FIG. 2), the transistor 24 is formed in an upper part (or a part closer to the base of the Y-axis) of the bias circuit region 81 in the figure. The emitter of the transistor 24 is electrically connected to the bump BMP21 via a wire 93 formed on or in the semiconductor substrate 71.

Also, the transistor 34 is formed in a lower part (or a part facing the Y-axis direction) of the bias circuit region 81 in the figure. The emitter of the transistor 34 is electrically connected to the bump BMP21 via a wire 94 formed on or in the semiconductor substrate 71.

The transistor 24 and the transistor 34 may overlap the bump BMP21 in plan view. Here, “plan view” refers to a view of the semiconductor substrate 71 from a direction perpendicular to the major surface of the semiconductor substrate 71 (or a direction opposite to the Z-axis direction).

### Effects

The bias circuit 16 of the first embodiment may respond too sensitively to the heat generated by the multiple unit transistors 15a because the transistor 32 is thermally coupled to the multiple unit transistors 15a. That is, the power amplifier circuit 1 may respond too sensitively to the heat generated by the amplifier transistor 15.

On the other hand, the bias circuit 16A of the second embodiment includes, in addition to the transistor 32 thermally coupled to the multiple unit transistors 15a, the transistor 34 not thermally coupled to the multiple unit transistors 15a. The transistor 32 and the transistor 34 are connected in parallel with each other. Because the transistor 34 does not receive the heat generated by the multiple unit transistors 15a, the emitter current (the electric current I30) of the transistor 34 is not influenced by the heat generated by the multiple unit transistors 15a. Accordingly, compared to the first embodiment, the variation in the base bias current (the electric current I26) of the amplifier transistor 15 is reduced.

This makes it possible to prevent the bias circuit 16A from responding too sensitively to the heat generated by the amplifier transistor 15. In other words, this makes it possible to prevent the power amplifier circuit 1A from responding too sensitively to the heat generated by the amplifier transistor 15.

Also, with the configuration in which the transistor 24 and the transistor 34 overlap the bump BMP21 in plan view, stress is also applied to the transistor 24 and the transistor 34. This makes it possible to reduce the influence of the stress on the amplifier transistor 15 and thereby makes it possible to reduce the degradation of the output characteristics.

Here, the response of the bias circuit 16A to the heat generated by the amplifier transistor 15 can be adjusted by adjusting the size of the transistor 32 and the size of the transistor 34. In the present disclosure, the size of each of the transistor 32 and the transistor 34 indicates an emitter area.

The bias circuit 13A also operates similarly to the bias circuit 16A described above. This makes it possible to prevent the power amplifier circuit 1A from responding too sensitively to the heat generated by the amplifier transistor 12.

Here, the response of the bias circuit 13A to the heat generated by the amplifier transistor 12 can be adjusted by adjusting the size of the transistor 22 and the size of the transistor 24. In the present disclosure, the size of each of the transistor 22 and the transistor 24 indicates an emitter area.

In the second embodiment, it is assumed that the technology of the present disclosure is applied to both stages of a multi-stage amplifier circuit (that is, the amplifier transistor 12 and the bias circuit 13, and the amplifier transistor 15 and the bias circuit 16). However, the present disclosure is not limited to this embodiment. The technology of the present disclosure may be applied to at least one of the stages of a multi-stage amplifier circuit.

### Third Embodiment

### Circuit Configuration

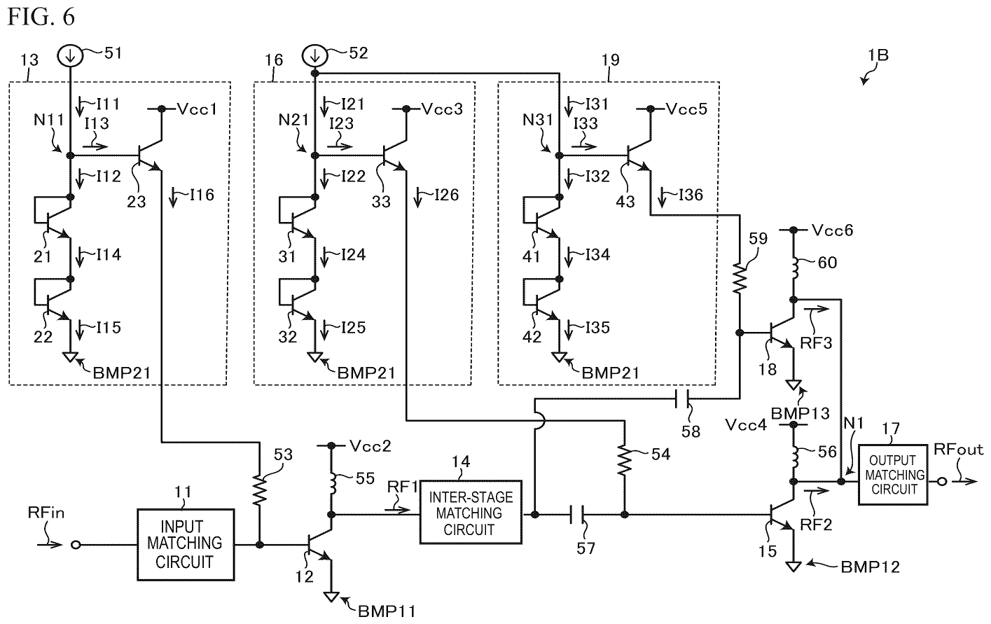

FIG. 6 is a diagram illustrating a circuit configuration of a power amplifier circuit according to a third embodiment.

Compared to the power amplifier circuit 1 (see FIG. 1), a power amplifier circuit 1B further includes an amplifier transistor 18 and a bias circuit 19.

In the present embodiment, the amplifier transistor 18 is assumed to be a multi-finger transistor. However, the present disclosure is not limited to this embodiment. The amplifier transistor 18 may be a unit transistor.

The amplifier transistor 15 and the amplifier transistor 18 are connected in parallel with each other. That is, the final stage (or the power stage) of the power amplifier circuit 1B is constituted by the amplifier transistor 15 and the amplifier transistor 18 that are connected in parallel with each other.

The bias circuit 19 biases the amplifier transistor 18. The bias circuit 19 includes transistors 41 through 43.

In the present embodiment, each of the transistors 41 through 43 is assumed to be a unit transistor. However, the present disclosure is not limited to this embodiment. Each of the transistors 41 through 43 may be a multi-finger transistor.

The collector and the base of the transistor 41 are electrically connected to a node N31. That is, the transistor 41 is diode-connected. The emitter of the transistor 41 is electrically connected to the collector and the base of the transistor 42. That is, the transistor 42 is diode-connected. The emitter of the transistor 42 is electrically connected to the bump BMP21. That is, the emitter of the transistor 42 is electrically connected to the reference potential via the bump BMP21.

The base of the transistor 43 is electrically connected to the node N31. The collector of the transistor 43 is electrically connected to and receives power from a power supply potential Vcc5. The emitter of the transistor 43 is electrically connected to a first end of a resistor 59. In other words, the transistor 43 is connected to the resistor 59 in an emitter-follower configuration. A second end of the resistor 59 is electrically connected to the base of the amplifier transistor 18.

An electric current I31 is input from the current source 52 to the node N31. The electric current I31 is divided into an electric current I32 and an electric current I33. That is, I31=I32+I33.

The electric current I32 is input to the collector and the base of the transistor 41. The transistor 41 outputs an electric current I34 from the emitter to the collector and the base of the transistor 32. That is, I32=I34. The transistor 42 outputs an electric current I35 from the emitter to the bump BMP21. That is, I34=I35. The transistor 41 and the transistor 42 generate a voltage at the node N31.

The transistor 43 outputs an electric current I36 corresponding to the electric current I33 to the base of the amplifier transistor 18 via the resistor 59. The base of the amplifier transistor 18 is biased by the electric current I36. That is, the electric current I36 is a base bias current of the amplifier transistor 18.

The emitter of the amplifier transistor 18 is electrically connected to a bump BMP13 (described later). The bump BMP13 is electrically connected to the reference potential. That is, the emitter of the amplifier transistor 18 is electrically connected to the reference potential via the bump BMP13. The collector of the amplifier transistor 18 is electrically connected to and receives power from a power supply potential Vcc6 via a choke coil 60.

A DC blocking capacitor 57 is added between the second end of the inter-stage matching circuit 14 and the base of the amplifier transistor 15. The DC blocking capacitor 58 is added between the second end of the inter-stage matching circuit 14 and the base of the amplifier transistor 18.

The collector of the amplifier transistor 15 is electrically connected to a node N1. The amplifier transistor 15 amplifies the radio frequency signal RF1 input to the base and outputs an amplified radio frequency signal RF2 from the collector to the node N1.

The collector of the amplifier transistor 18 is electrically connected to the node N1. The amplifier transistor 18 amplifies the radio frequency signal RF1 input to the base and outputs an amplified radio frequency signal RF3 from the collector to the node N1.

The radio frequency signal RF2 and the radio frequency signal RF3 are superimposed on each other at the node N1 to form a radio frequency signal RFout.

The first end of the output matching circuit 17 is electrically connected to the node N1. The radio frequency signal RFout is output from the second end of the output matching circuit 17.

### Layout

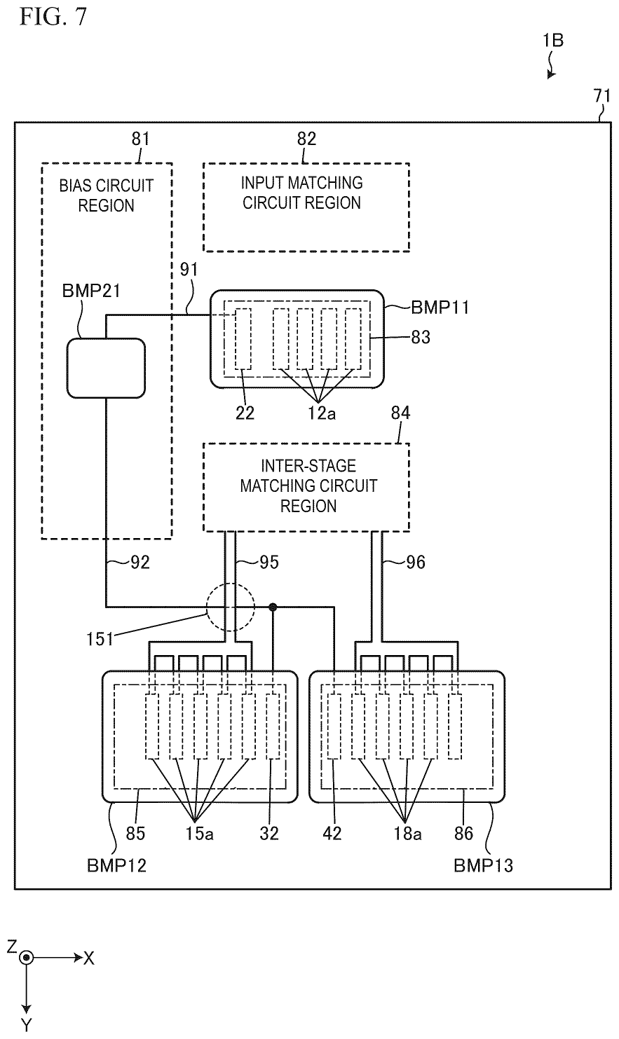

FIG. 7 is a diagram illustrating a layout of the power amplifier circuit according to the third embodiment. The power amplifier circuit 1B is formed on or in the semiconductor substrate 71. FIG. 7 is a plan view of the semiconductor substrate 71 seen from a direction perpendicular to the major surface.

A region 85 is provided, in the figure, on the lower sides (or sides facing the Y-axis direction) of the bias circuit region 81 and the inter-stage matching circuit region 84. The longitudinal direction of the region 85 corresponds to the X-axis direction, and the transverse direction of the region 85 corresponds to the Y-axis direction. The transistor 32 and the multiple unit transistors 15a are formed in the region 85. The multiple unit transistors 15a constitute the amplifier transistor 15.

The transistor 32 is formed along the right side (or a side facing the X-axis direction) of the region 85 in the figure. Also, the multiple unit transistors 15a are formed on the left side (or a side closer to the base of the X-axis) of the transistor 32 in the figure. The longitudinal direction of each of the transistor 32 and the multiple unit transistors 15a corresponds to the Y-axis direction, and the transverse direction of each of the transistor 32 and the multiple unit transistors 15a corresponds to the X-axis direction. The transistor 32 and the multiple unit transistors 15a are arranged in the longitudinal direction of the region 85 (or in the X-axis direction).

The emitter of the transistor 32 is electrically connected to the bump BMP21 via the wire 92 formed on or in the semiconductor substrate 71.

The wire 92 is an example of a “first wire” of the present disclosure.

The base of each of the multiple unit transistors 15a is electrically connected to the inter-stage matching circuit 14 in the inter-stage matching circuit region 84 via a wire 95 formed in a layer of the semiconductor substrate 71 different from the layer in which the wire 92 is formed.

The wire 95 is an example of a “second wire” of the present disclosure.

The wire 92 and the wire 95 intersect each other in a region 151. In the region 151, parasitic capacitance may be generated between the wire 92 and the wire 95.

A region 86 is provided, in the figure, on the right side (or a side facing the X-axis direction) of the region 85 and on the lower side (or a side facing the Y-axis direction) of the inter-stage matching circuit region 84. The longitudinal direction of the region 86 corresponds to the X-axis direction, and the transverse direction of the region 86 corresponds to the Y-axis direction. The transistor 42 and multiple unit transistors 18a are formed in the region 86. The multiple unit transistors 18a constitute the amplifier transistor 18.

The transistor 42 is formed along the left side (or a side closer to the base of the X-axis) of the region 86 in the figure. Also, the multiple unit transistors 18a are formed on the right side (or a side facing the X-axis direction) of the transistor 42. The longitudinal direction of each of the transistor 42 and the multiple unit transistors 18a corresponds to the Y-axis direction, and the transverse direction of each of the transistor 42 and the multiple unit transistors 18a corresponds to the X-axis direction. The transistor 42 and the multiple unit transistors 18a are arranged in the longitudinal direction of the region 86 (or in the X-axis direction).

The emitter of the transistor 42 is electrically connected to the bump BMP21 via the wire 92.

The base of each of the multiple unit transistors 18a is electrically connected to the inter-stage matching circuit 14 in the inter-stage matching circuit region 84 via a wire 96 formed on or in the semiconductor substrate 71.

The bump BMP13 is formed in an upper layer (or a foreground layer in the figure) of the region 86 via an insulating layer. The bump BMP13 overlaps the region 86 (the transistor 42 and the multiple unit transistors 18a) in plan view. Here, “plan view” refers to a view of the semiconductor substrate 71 from a direction perpendicular to the major surface of the semiconductor substrate 71 (or a direction opposite to the Z-axis direction).

For example, copper (Cu) is used for the bump BMP13. A low-resistance metallic material other than copper, such as aluminum (Al) or gold (Au), may also be used for the bump BMP13.

An under bump metal may be formed between the insulating layer and the bump BMP13.

### Effects

There may be a case in which the wire 92, which electrically connects the transistor 32 to the bump BMP21, needs to intersect another wire. Even in this case, because the wire 92 intersects the wire 95 that is electrically connected to the base of each of the multiple unit transistors 15a, it is possible to achieve an intersection with small parasitic capacitance.

This makes it possible to reduce the degradation of the output characteristics of the power amplifier circuit 1B.

Here, the third embodiment and the second embodiment may be combined. That is, the bias circuit 13 may further include the transistor 24 that is connected in parallel with the transistor 22. The bias circuit 16 may further include the transistor 34 that is connected in parallel with the transistor 32. Similarly, the bias circuit 19 may further include a transistor that is connected in parallel with the transistor 42.

In the third embodiment, it is assumed that the technology of the present disclosure is applied to both stages of a multi-stage amplifier circuit (that is, the amplifier transistor 12 and the bias circuit 13, and the amplifier transistors 15 and 18 and the bias circuits 16 and 19). However, the present disclosure is not limited to this embodiment. The technology of the present disclosure may be applied to at least one of the stages of a multi-stage amplifier circuit.

### Fourth Embodiment

### Circuit Configuration

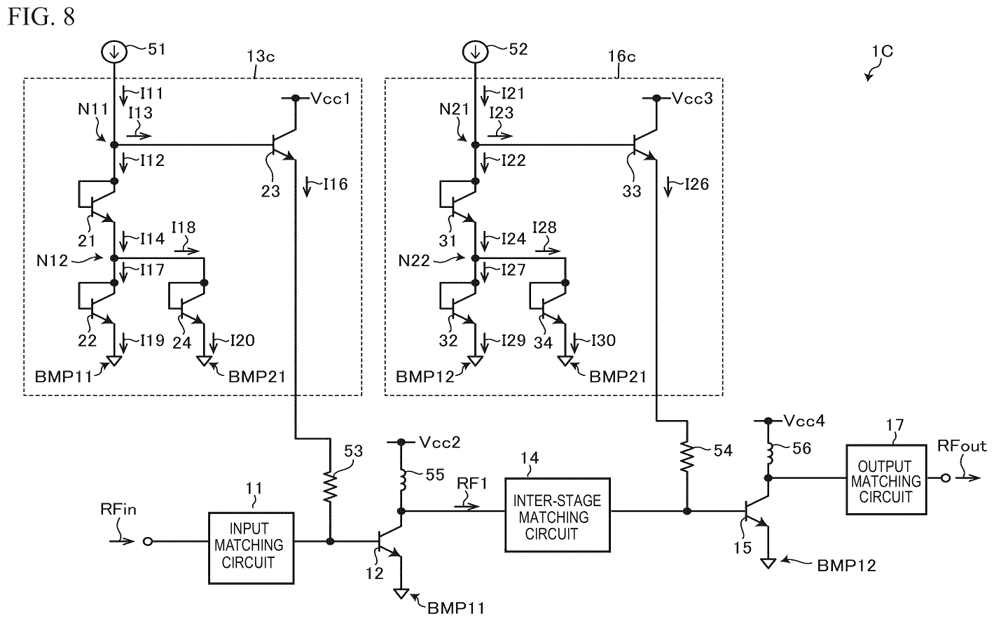

FIG. 8 is a diagram illustrating a circuit configuration of a power amplifier circuit according to a fourth embodiment.

Compared to the power amplifier circuit 1A (see FIG. 4), a power amplifier circuit 1C includes a bias circuit 13C instead of the bias circuit 13A. Also, the power amplifier circuit 1C also includes a bias circuit 16C instead of the bias circuit 16A.

In the bias circuit 13C, the emitter of the transistor 22 is electrically connected to the bump BMP11.

In the bias circuit 16C, the emitter of the transistor 32 is electrically connected to the bump BMP12.

### Layout

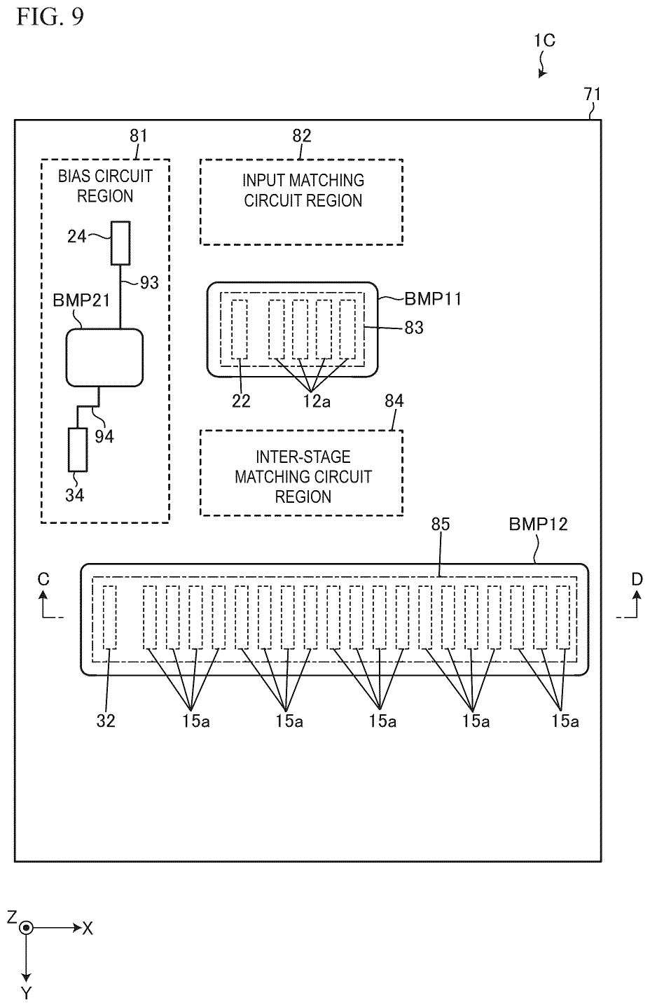

FIG. 9 is a diagram illustrating a layout of the power amplifier circuit according to the fourth embodiment. The power amplifier circuit 1C is formed on or in the semiconductor substrate 71. FIG. 9 is a plan view of the semiconductor substrate 71 seen from a direction perpendicular to the major surface.

Different from the power amplifier circuit 1A (see FIG. 5), the wire 91 and the wire 92 are not formed in the power amplifier circuit 1C. Instead, the emitter of the transistor 22 is electrically connected to the bump BMP11. Also, the emitter of the transistor 32 is electrically connected to the bump BMP12.

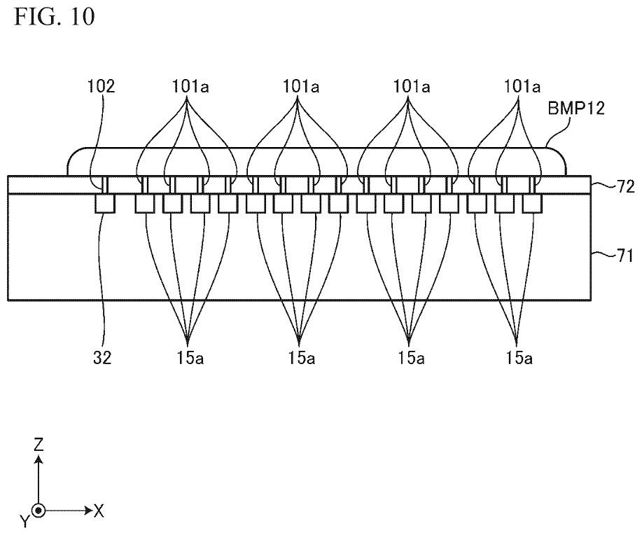

FIG. 10 is a cross-sectional view of the power amplifier circuit according to the fourth embodiment. FIG. 10 is a cross-sectional view taken along line C-D in FIG. 9.

FIG. 10 illustrates cross sections of the transistor 32, the multiple unit transistors 15a, and the bump BMP12. Because the cross sections of the transistor 22, the multiple unit transistors 12a, and the bump BMP11 are substantially the same as those in FIG. 10, their illustration and descriptions are omitted.

The emitter of the transistor 32 is electrically connected to the bump BMP12 through a via 102.

### Effects

Referring to FIG. 10, the heat generated by the multiple unit transistors 15a is transmitted to the transistor 32 via the semiconductor substrate 71, the insulating layer 72, the bump BMP12, and the via 102. In other words, the multiple unit transistors 15a and the transistor 32 are thermally coupled to each other. When heat is transferred to the transistor 32 and the temperature of the transistor 32 increases, the threshold of the base-emitter voltage increases. Accordingly, the change in the threshold of the base-emitter voltage of the amplifier transistor 15 due to the temperature increase is compensated for by the increase in the base bias current (the electric current I26).

This makes it possible to reduce the degradation of the output characteristics of the power amplifier circuit 1 even when the amplifier transistor 15 heats up.

The bias circuit 16C includes, in addition to the transistor 32 thermally coupled to the multiple unit transistors 15a, the transistor 34 not thermally coupled to the multiple unit transistors 15a. The transistor 32 and the transistor 34 are connected in parallel with each other. Because the transistor 34 does not receive the heat generated by the multiple unit transistors 15a, the emitter current (the electric current I30) of the transistor 34 is not influenced by the heat. Accordingly, compared to the first embodiment, the variation in the base bias current (the electric current I26) of the amplifier transistor 15 is reduced.

This makes it possible to prevent the bias circuit 16C from responding too sensitively to the heat generated by the amplifier transistor 15. In other words, this makes it possible to prevent the power amplifier circuit 1C from responding too sensitively to the heat generated by the amplifier transistor 15.

Here, the response of the bias circuit 16C to the heat generated by the amplifier transistor 15 can be adjusted by adjusting the size of the transistor 32 and the size of the transistor 34.

The bias circuit 13C also operates similarly to the bias circuit 16C described above. This makes it possible to reduce the degradation of the output characteristics of the power amplifier circuit 1C even when the amplifier transistor 12 heats up.

Here, the response of the bias circuit 13C to the heat generated by the amplifier transistor 12 can be adjusted by adjusting the size of the transistor 22 and the size of the transistor 24.

Furthermore, when the amplifier transistor 15 (the multiple unit transistors 15a) receives stress from the bump BMP12 through the vias 101a, the threshold of the base-emitter voltage increases, the operating point changes, the quiescent current changes, the gain changes, and the linearity is degraded.

Referring to FIG. 10, the transistor 32 is electrically connected to the bump BMP12 through the via 102. With this configuration, the transistor 32 receives, from the bump BMP12 through the via 102, stress that is equivalent to the stress received by the multiple unit transistors 15a from the bump BMP12 through the vias 101a.

When the threshold of the base-emitter voltage of the multiple unit transistors 15a changes due to the stress, the threshold of the base-emitter voltage of the transistor 32 also changes due to the stress. Accordingly, the change in the threshold of the base-emitter voltage of the amplifier transistor 15 due to stress is compensated for by the increase in the base bias current (the electric current I26). As a result, the variation in the quiescent current of the amplifier transistor 15 is reduced, the variation in the gain is reduced, and the degradation of the linearity is reduced.

This makes it possible to reduce the degradation of the output characteristics of the power amplifier circuit 1C even when stress is applied to the amplifier transistor 15.

Here, the response of the bias circuit 16C to the stress applied to the amplifier transistor 15 can be adjusted by adjusting the size of the transistor 32 and the size of the transistor 34.

The transistor 22 and the amplifier transistor 12 also operate similarly to the transistor 32 and the amplifier transistor 15 described above. This makes it possible to reduce the degradation of the output characteristics of the power amplifier circuit 1C even when stress is applied to the amplifier transistor 12 from the bump BMP11.

Here, the response of the bias circuit 13C to the stress applied to the amplifier transistor 12 can be adjusted by adjusting the size of the transistor 22 and the size of the transistor 24.

### Fifth Embodiment

### Circuit Configuration

The circuit configuration of a fifth embodiment is substantially the same as the circuit configuration of the first embodiment (see FIG. 1). Therefore, the illustration and descriptions of the circuit configuration of the fifth embodiment are omitted.

### Layout

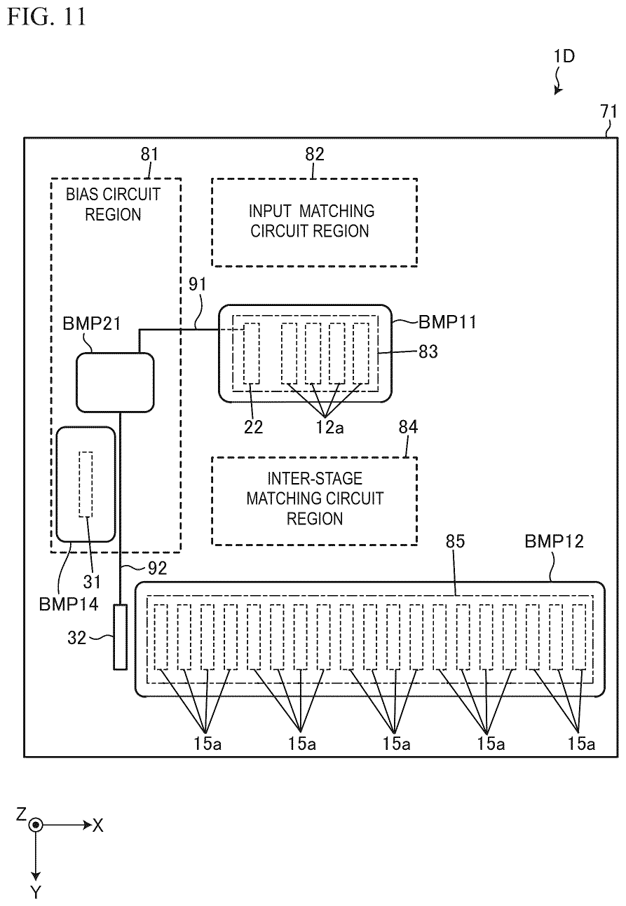

FIG. 11 is a diagram illustrating a layout of a power amplifier circuit according to the fifth embodiment. A power amplifier circuit 1D is formed on or in the semiconductor substrate 71. FIG. 11 is a plan view of the semiconductor substrate 71 seen from a direction perpendicular to the major surface.

In the power amplifier circuit 1D, different from the power amplifier circuit 1 (see FIG. 2), the transistor 32 and the bump BMP12 do not overlap each other when seen from a direction perpendicular to the major surface of the semiconductor substrate 71.

Also, the transistor 31 is formed in the bias circuit region 81. Furthermore, a bump BMP14 is formed in a layer above the transistor 31 (or a foreground layer in the figure) via an insulating layer. The bump BMP14 overlaps the transistor 31 in a view of the semiconductor substrate 71 seen from a direction perpendicular to the major surface of the semiconductor substrate 71.

### Effects

The power amplifier circuit 1 of the first embodiment may respond too sensitively to the heat generated by the multiple unit transistors 15a because the transistor 32 overlaps the bump BMP12 in a view of the semiconductor substrate 71 seen from a direction perpendicular to the major surface of the semiconductor substrate 71. That is, the power amplifier circuit 1 may respond too sensitively to the heat generated by the amplifier transistor 15.

On the other hand, in the power amplifier circuit 1D of the fifth embodiment, the transistor 32 does not overlap the bump BMP12 in a view of the semiconductor substrate 71 seen from a direction perpendicular to the major surface of the semiconductor substrate 71. Accordingly, compared to the power amplifier circuit 1, the power amplifier circuit 1D can reduce the thermal coupling between the transistor 32 and the amplifier transistor 15.

This makes it possible to prevent the power amplifier circuit 1D from responding too sensitively to the heat generated by the amplifier transistor 15.

Also, in the power amplifier circuit 1D, the transistor 31 overlaps the bump BMP14 in a view of the semiconductor substrate 71 seen from a direction perpendicular to the major surface of the semiconductor substrate 71.

With this configuration of the power amplifier circuit 1D, when stress is applied to the semiconductor substrate 71, the transistor 31 is also subjected to the stress. This makes it possible to reduce the influence of the stress on the amplifier transistor 15 and thereby makes it possible to reduce the degradation of the output characteristics.

Although the final stage (the transistor 31 and the transistor 32) of a multi-stage amplifier circuit is described above, the first stage (the transistor 21 and the transistor 22) of the multi-stage amplifier circuit may also have a configuration similar to the configuration of the final stage. That is, the transistor 22 may be disposed so as not to overlap the bump BMP11 in a view of the semiconductor substrate 71 seen from a direction perpendicular to the major surface of the semiconductor substrate 71. Also, the transistor 21 may be disposed to overlap a bump different from the bump BMP11 in a view of the semiconductor substrate 71 seen from a direction perpendicular to the major surface of the semiconductor substrate 71. The technology of the present disclosure may be applied to at least one of the stages of a multi-stage amplifier circuit.

### Examples of Configurations of Present Disclosure

The present disclosure may be implemented by configurations as described below.

(1) A power amplifier circuit includes a first transistor formed on a semiconductor substrate; a second transistor that is formed on the semiconductor substrate, includes a base to which a first current is supplied as a part of control currents, and supplies a bias current based on the first current to the first transistor; a third transistor that is formed on the semiconductor substrate, includes a collector to which a second current is supplied as a part of the control currents, and includes an emitter that outputs a third current based on the second current; a first metal part that is electrically connected to an emitter of the first transistor and is disposed, in plan view of the semiconductor substrate, to overlap a first layout region in which the first transistor is disposed; and a second metal part that is electrically connected to the emitter of the third transistor. The third transistor is disposed to overlap the first metal part in the plan view.

(2) The power amplifier circuit described in (1) further includes a fourth transistor that is formed on the semiconductor substrate, includes a collector to which the second current is supplied as a part of the control currents, is connected in parallel with the third transistor, and includes an emitter that outputs a fourth current based on the second current. The emitter of the fourth transistor is electrically connected to the second metal part.

(3) The power amplifier circuit described in (2). The fourth transistor is disposed to overlap the second metal part in the plan view.

(4) The power amplifier circuit described in any one of (1) to (3). A first wire electrically connecting the emitter of the third transistor to the second metal part intersects a second wire electrically connected to a base of the first transistor.

(5) The power amplifier circuit described in any one of (2) to (4). A size of the third transistor differs from a size of the fourth transistor.

(6) The power amplifier circuit described in any one of (1) to (5) further includes a fifth transistor that is formed on the semiconductor substrate, includes a collector and a base that are electrically connected to each other and to which a fifth current is supplied as a part of the control currents, and includes an emitter that outputs the second current. The collector and a base of the third transistor are electrically connected to each other.

(7) A power amplifier circuit includes a first transistor formed on a semiconductor substrate; a second transistor that is formed on the semiconductor substrate, includes a base to which a first current is supplied as a part of control currents, and supplies a bias current based on the first current to the first transistor; a third transistor that is formed on the semiconductor substrate, includes a collector to which a second current is supplied as a part of the control currents, and includes an emitter that outputs a third current based on the second current; a fourth transistor that is formed on the semiconductor substrate, includes a collector to which the second current is supplied, is connected in parallel with the third transistor, and includes an emitter that outputs a fourth current based on the second current; and a first metal part that is electrically connected to an emitter of the first transistor and is disposed, in plan view of the semiconductor substrate, to overlap a first layout region in which the first transistor is disposed. The emitter of the third transistor is electrically connected to the first metal part.

(8) The power amplifier circuit described in (7) further includes a fifth transistor that is formed on the semiconductor substrate, includes a collector and a base that are electrically connected to each other and to which a fifth current is supplied as a part of the control currents, and includes an emitter that outputs the second current. The collector and a base of the third transistor are electrically connected to each other, and the collector and a base of the fourth transistor are electrically connected to each other.

The above-described embodiments are intended to facilitate the understanding of the present disclosure and are not intended to limit the scope of the present disclosure. The present disclosure may be modified or improved without necessarily departing from the spirit of the present disclosure, and the present disclosure may include its equivalents.

What is claimed is:

1. A power amplifier circuit comprising:
a first transistor on a semiconductor substrate;
a second transistor that is on the semiconductor substrate, that has a base to which a first current is supplied as a part of control currents, and that is configured to supply a bias current based on the first current to the first transistor;
a third transistor that is on the semiconductor substrate, that has a collector to which a second current is supplied as a part of the control currents, and that has an emitter configured to output a third current based on the second current;
a first metal part that is electrically connected to an emitter of the first transistor and that overlaps, in a plan view of the semiconductor substrate, a first layout region in which the first transistor is located; and
a second metal part that is electrically connected to the emitter of the third transistor,
wherein the third transistor overlaps the first metal part in the plan view.

2. The power amplifier circuit according to claim 1, further comprising:
a fourth transistor that is on the semiconductor substrate, that has a collector to which the second current is supplied as a part of the control currents, that is connected in parallel with the third transistor, and that has an emitter configured to output a fourth current based on the second current,
wherein the emitter of the fourth transistor is electrically connected to the second metal part.

3. The power amplifier circuit according to claim 2, wherein the fourth transistor overlaps the second metal part in the plan view.

4. The power amplifier circuit according to claim 1, wherein a first wire electrically connecting the emitter of the third transistor to the second metal part intersects a second wire electrically connected to a base of the first transistor.

5. The power amplifier circuit according to claim 2, wherein a size of the third transistor is different than a size of the fourth transistor.

6. The power amplifier circuit according to claim 1, further comprising:
a fifth transistor that is on the semiconductor substrate, that has a collector and a base that are electrically connected to each other and to which a fifth current is supplied as a part of the control currents, and that has an emitter configured to output the second current,
wherein the collector and a base of the third transistor are electrically connected to each other.

7. A power amplifier circuit comprising:
a first transistor on a semiconductor substrate;
a second transistor that is on the semiconductor substrate, that has a base to which a first current is supplied as a part of control currents, and that is configured to supply a bias current based on the first current to the first transistor;
a third transistor that is on the semiconductor substrate, that has a collector to which a second current is supplied as a part of the control currents, and that has an emitter configured to output a third current based on the second current;
a fourth transistor that is on the semiconductor substrate, that has a collector to which the second current is supplied, that is connected in parallel with the third transistor, and that has an emitter configured to output a fourth current based on the second current; and
a first metal part that is electrically connected to an emitter of the first transistor and overlaps, in a plan view of the semiconductor substrate, a first layout region in which the first transistor is located,
wherein the emitter of the third transistor is electrically connected to the first metal part.

8. The power amplifier circuit according to claim 7, further comprising:
a fifth transistor that is on the semiconductor substrate, that has a collector and a base that are electrically connected to each other and to which a fifth current is supplied as a part of the control currents, and that has an emitter configured to output the second current,
wherein the collector and a base of the third transistor are electrically connected to each other, and
wherein the collector and a base of the fourth transistor are electrically connected to each other.
